(19) United States
(12) Patent Application Publication
(10) Pub. No.: US 2005/0170622 A1
(43) Pub. Date: Aug. 4, 2005

(54) Method for manufacturing wiring substrate and method for manufacturing electronic device

(76) Inventors: Satoshi Kimura, Nagano-ken (JP); Hidemichi Furihata, Chino-shi (JP); Minoru Marumo, Nagano-ken (JP); Tomohiko Sogo, Nagoya-shi (JP)

Correspondence Address: HARNESS, DICKEY & PIERCE, P.L.C., P.O. BOX 828, BLOOMFIELD HILLS, MI, 48303, US

(21) Appl. No.: 11/050,254

(22) Filed: Feb. 3, 2005

(30) Foreign Application Priority Data
Feb. 4, 2004 (JP) 2004-028118

(51) Int. Cl. H01L 21/20

(52) U.S. Cl. 438/584

(57) ABSTRACT

A method for manufacturing a wiring substrate includes the steps of (a) irradiating a vacuum ultraviolet radiation on a second area of a substrate having a first area and the second area to thereby break down an interatomic bond in the second area of the substrate, (b) providing a catalyst in the first and second areas of the substrate, (c) washing the substrate to thereby remove a portion of the catalyst provided in the second area, and (d) depositing a metal layer on a portion of the catalyst remaining in the first area to thereby form a wiring composed of the metal layer along the first area.

### RELATED APPLICATIONS

This application claims priority to Japanese Patent Application No. 2004-028118 filed Feb. 4, 2004 which is hereby expressly incorporated by reference herein in its entirety.

### BACKGROUND

1. Technical Field

The present invention relates to a method for manufacturing wiring substrates and a method for manufacturing electronic devices.

2. Related Art

A subtractive method and an additive method are known as a method for forming wirings on a flexible substrate. In the subtractive method, a metal layer is formed over the entire surface of a flexible substrate, a photoresist is formed on the metal layer by patterning, and the metal layer is etched by using the photoresist as a barrier. In the additive method, a photoresist is formed on a flexible substrate by patterning, and a metal layer is deposited by a plating process in an opening section in the photoresist.

These methods entail problems concerning consumptions of resources and raw material, in view of the fact that the photoresist is finally removed, and further in view of the fact that a part of the metal layer is removed in the subtractive method. Also, they require the steps of forming and removing a photoresist, which results in a problem of a large number of manufacturing steps. Furthermore, because the measurement accuracy of wirings depends on the resolution of a photoresist, there is a limit in forming wirings at a higher level of accuracy.

It is an object of the present invention to deposit a metal layer only in a required portion, and form wirings with a simple manufacturing process.

### SUMMARY

A method for manufacturing a wiring substrate in accordance with the present invention includes the steps of:
(a) irradiating a vacuum ultraviolet radiation on a second area of a substrate having a first area and the second area to thereby break down an interatomic bond in the second area of the substrate;
(b) providing a catalyst in the first and second areas of the substrate;
(c) washing the substrate to thereby remove a portion of the catalyst provided in the second area; and
(d) depositing a metal layer on a portion of the catalyst remaining in the first area to thereby form a wiring composed of the metal layer along the first area.

According to the present invention, the catalyst is patterned by irradiation of a vacuum ultraviolet radiation. By this, a metal layer can be precipitated only on a required portion along a predetermined pattern configuration. Accordingly, for example, there is no need to form a mask with a resist layer, and a waste of material can be reduced, and highly accurate wirings can be formed at a low cost with a simple and short-time manufacturing process.

In the method for manufacturing a wiring substrate, before the step (a), a surface layer portion composed of a reforming layer including a C—F bond in the first and second areas of the substrate may be formed. By this, effects similar to substrate cleaning and surface roughening treatment can be obtained. Also, due to the fact that the reforming layer has a water-repelling function, the moisture resistance of the substrate improves.

In the method for manufacturing a wiring substrate, before the step (a), a surface layer portion composed of a hydrolyzed layer in the first and second areas of the substrate may be formed by conducting an alkaline washing. By this, effects similar to substrate cleaning and surface roughening treatment can be obtained.

The method for manufacturing a wiring substrate may include, in the step (a), the step of injecting the vacuum ultraviolet radiation deeper than the thickness of the surface layer portion, and in the step (c), the step of washing the substrate to thereby remove a portion of the surface layer portion in the second area. By this, the surface layer portion composed of the reforming layer or the hydrolyzed layer is removed, such that the portion of the catalyst provided in the second area can be securely removed.

In the method for manufacturing a wiring substrate, before the step (b), the step of providing a surface-active agent in the first and second areas of the substrate may be further included, wherein, in the step (b), the catalyst may be provided on the surface-active agent. By this, the catalyst can be stably provided.

In the method for manufacturing a wiring substrate, the surface-active agent may be a cationic system surface-active agent.

In the method for manufacturing a wiring substrate, the surface-active agent may be an anionic system surface-active agent.

In the method for manufacturing a wiring substrate, in the step (b), the substrate may be dipped in a solution including tin chloride, and then dipped in a catalyst liquid including palladium chloride, to thereby deposit palladium as the catalyst.

In the method for manufacturing a wiring substrate, in the step (b), the substrate may be dipped in a catalyst liquid including tin-palladium, to remove tin from the substrate, to thereby deposit palladium as the catalyst.

In the method for manufacturing a wiring substrate, the substrate may have at least one of a C—C, C═C, C—F, C—H, C—Cl, C—N, C—O, N—H and O—H bond.

In the method for manufacturing a wiring substrate, the substrate may have at least a C═C bond, and the vacuum ultraviolet radiation may have at least a property that can break up the C═C bond.

In the method for manufacturing a wiring substrate, a light source of the vacuum ultraviolet radiation may be an excimer lamp having Xe gas enclosed therein.

A method for manufacturing an electronic device in accordance with the present invention includes the method for manufacturing a wiring substrate described above, and further includes the steps of mounting a semiconductor chip having an integrated circuit on the wiring substrate, and electrically connecting the wiring substrate to a circuit substrate. According to the present invention, a waste of material can be reduced, and highly accurate wirings can be formed at a low cost with a simple and short-time manufacturing process.

### BRIEF DESCRIPTION OF THE DRAWINGS

FIG. 1(A)-FIG. 1(C) are views illustrating a method for manufacturing a wiring substrate in accordance with a first embodiment of the present invention.

FIG. 2(A)-FIG. 2(C) are views illustrating the method for manufacturing a wiring substrate in accordance with the first embodiment of the present invention.

FIG. 3(A)-FIG. 3(D) are views illustrating a method for manufacturing a wiring substrate in accordance with a modified example of the first embodiment of the present invention.

FIG. 4(A)-FIG. 4(C) are views illustrating the method for manufacturing a wiring substrate in accordance with the modified example of the first embodiment of the present invention.

FIG. 5(A)-FIG. 5(C) are views illustrating a method for manufacturing a wiring substrate in accordance with a modified example of the first embodiment of the present invention.

FIG. 6(A)-FIG. 6(C) are views illustrating the method for manufacturing a wiring substrate in accordance with the modified example of the first embodiment of the present invention.

FIG. 7 is a view illustrating an electronic device in accordance with a second embodiment of the present invention.

### DETAILED DESCRIPTION

Embodiments of the present invention are described below with reference to the accompanying drawings.

### First Embodiment

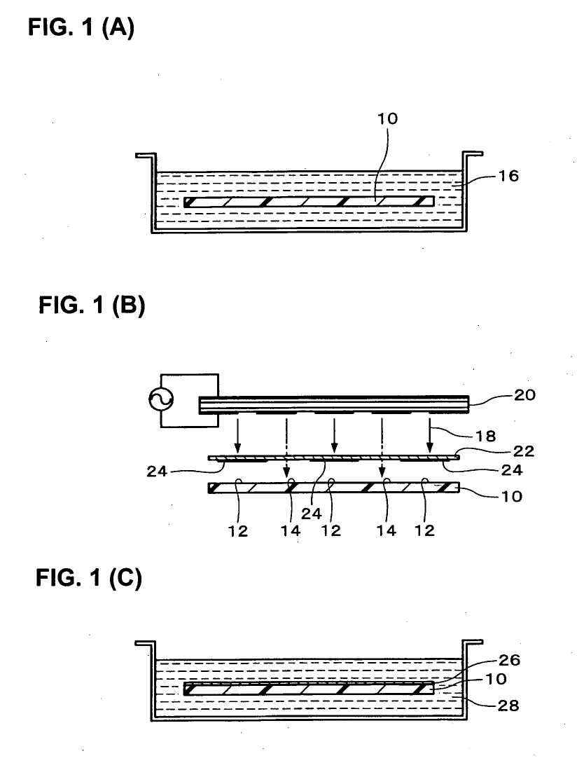

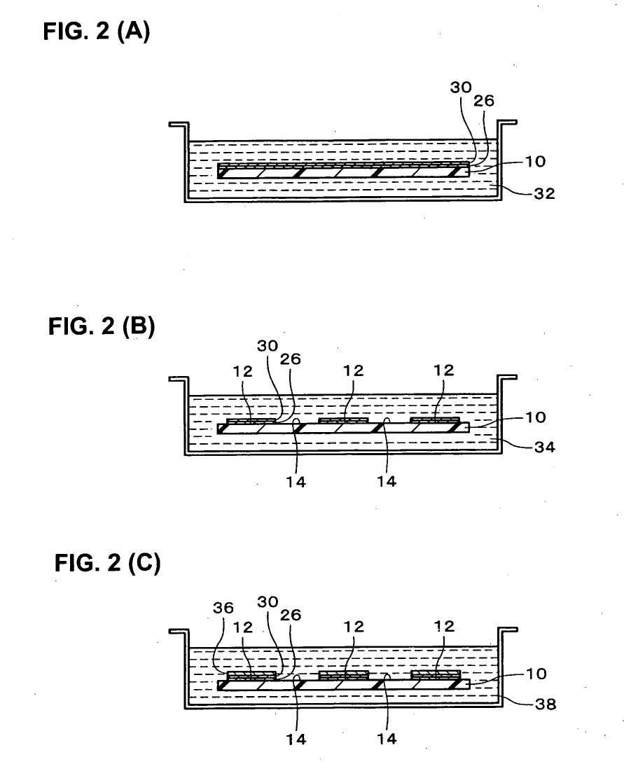

FIG. 1(A)-FIG. 2(C) are views illustrating a method for manufacturing a wiring substrate in accordance with an embodiment of the present invention. In the present embodiment, a wiring substrate is manufactured using an electroless plating method.

A substrate (sheet) 10 may be a flexible substrate. As the flexible substrate, a FPC (Flexible Printed Circuit), a COF (Chip On Film) substrate, or a TAB (Tape Automated Bonding) substrate may be used. The substrate 10 is formed from an organic material (for example, resin). As the substrate 10, a polyimide substrate or a polyester substrate may be used. The substrate 10 has an organic interatomic bond. The substrate 10 may have at least one of a C—C, C═C, C—F, C—H, C—Cl, C—N, C—O, N—H and O—H bond. The substrate 10 may have at least a C═C bond. In the present embodiment, a wiring is formed on one of surfaces of the substrate 10. Alternatively, wirings may be formed on both of the surfaces of the substrate 10. The substrate 10 has a first area 12 and a second area 14 (see FIG. 1 (B)). The first area 12 and the second area 14 are areas in the surface of the substrate 10 where wirings are formed.

As shown in FIG. 1(A), first, dirt on the surface of the substrate 10 may be washed (cleaned). As a washing method, the substrate 10 may be dipped in a washing solution 16 such as an acid, an alkali, an organic solvent or water. Concretely, a solution of hydrochloride system or an alcohol such as IPA or the like may be used as the washing solution 16.

The substrate 10 may be washed with an alkali by dipping in an alkaline solution (for example, an inorganic alkali solution). More specifically, the substrate 10 may be dipped in or washed with a solution of sodium hydroxide with a concentration of 1 wt %-10 wt % at room temperature for about 10-60 minutes (for example, 30 minutes). Cleaning and surface roughening treatment of the substrate 10 can be conducted at the same time by the alkali washing. As a result, the adhesion of a metal layer (wiring) can be improved.

As shown in FIG. 1(B), a vacuum ultraviolet radiation (VUV; vacuum ultraviolet radiation) 18 is irradiated to the second area 14 of the substrate 10. More specifically, a mask 22 is disposed between a source of light 20 and the substrate 10, and the vacuum ultraviolet radiation 18 is irradiated to the substrate 10 through the mask 22. The vacuum ultraviolet radiation 18 is covered by a pattern 24 of the mask 22, and penetrates other areas. When the vacuum ultraviolet radiation 18 is irradiated, the interatomic bond in the second area 14 of the substrate 10 is (chemically) broken down. In the present embodiment, the second area 14 of the substrate 10 is not mechanically cut. According to this method, the vacuum ultraviolet radiation 18 is used mainly for the action of dissolving the interatomic bond of the substrate 10, such that its energy consumption can be lowered compared with the case of cutting the substrate 10. As a result, for example, a heat distortion can be prevented from being generated in the substrate 10. Moreover, the method can prevent a part of the substrate 10 from dispersing and adhering to other parts.

It is noted here that, in the present embodiment, the first area 12 is an area where a metal layer (wiring) is formed, and has a predetermined pattern configuration. The second area 14 has a reversed configuration of the first area 12 in the surface of the substrate 10.

The vacuum ultraviolet radiation 18 may have a wavelength of 100 nm-200 nm (for example, 100 nm-180 nm). The vacuum ultraviolet radiation 18 has a property (for example, a wavelength) that can break down the organic interatomic bond. The vacuum ultraviolet radiation 18 may have a property (for example, a wavelength) that can break down at least a C═C bond of the substrate 10. It may have a property (for example, a wavelength) that can break down all of the interatomic bonds (composed of at least one of a C—C, C═C, C—F, C—H, C—Cl or C—N C—O, N—H and O—H bond) of the substrate 10. An excimer lamp enclosing Xe gas therein may be used as the source of light 20 (with a wavelength of 172 nm). Because a condenser lens for laser generation and the scanning time with a laser become unnecessary if the lamp is used, simplification of the manufacturing process can be achieved.

More specifically, a mask 22 is arranged over a wiring forming surface of the substrate 10, as shown in FIG. 1(B). The mask 22 may be a photomask, or may be a metal mask. For example, a high-purity silica glass for vacuum ultraviolet radiation (with a transmittance of vacuum ultraviolet radiation of 80% or more) having a pattern formed with chrome is used as the mask 22. Although the mask 22 is shown to be spaced from and above the substrate 10 in FIG. 1(B), the mask 22 is actually disposed on and in contact with the substrate 10. The source of light 20, the mask 22, and the substrate 10 are disposed in a nitrogen atmosphere. The vacuum ultraviolet radiation 18 is irradiated up to the distance of about 10 mm without attenuating in the nitrogen atmosphere.

When neither the substrate 10 nor the mask 22 comes in contact uniformly due to an elasticity and/or a warp of the substrate 10, an outer circumference portion of the mask 22 may be retained with a holder, and the back of the substrate 10 may be pressed toward the mask 22 side in an area of the same size as the mask 22. The source of light 20 is placed close to the substrate 10 as much as possible (for example, 10 mm or less). For example, as the source of light 20, an excimer VUV/03 Cleaning Unit (Manufacturer name; Ushio Electric Co., Model; UER20-172A/B, and Lamp specification; Dielectric barrier discharge excimer lamp enclosing Xe gas therein) may be used. When the raw material of the substrate 10 consists of polyimide, the output is adjusted to about 10 mW and irradiation is conducted for about ten minutes. The vacuum ultraviolet radiation 18 is irradiated to one of the surfaces of the substrate 10 in the present embodiment. However, when wirings are to be formed on both sides of the substrate 10, the vacuum ultraviolet radiation 18 may be irradiated to each of the faces of the substrate 10 one by one or to both of them at the same time.

A surface active agent 26 may be provided in the first and second areas 12 and 14 of the substrate 10, if necessary, as shown in FIG. 1 (C). In that case, the substrate 10 may be dipped in a surface active agent solution 28. The surface-active agent 26 may be provided over the entire area of one of the surfaces of the substrate 10.

A cationic system surface-active agent (a cation surface-active agent or one having a property equal to the same) that has a property to form positive ion may be used as the surface-active agent 26. For example, the substrate 10 is dipped in a cation surface-active agent solution of an alkyl ammonium chloride system at room temperature for about 30 seconds to three minutes, and then washed with pure water. Then, the substrate 10 is sufficiently dried in a room temperature atmosphere. When the surface potential of the substrate 10 is a negative potential, the negative potential on the surface of the substrate 10 can be neutralized or reversed to a positive potential by the cationic system surface-active agent used.

As a modified example, an anionic system surface-active agent (an anion surface-active agent or one having a property equal to the same) that has a property to make negative ion may be used as the surface-active agent 26. For example, the substrate 10 is dipped in an anion surface-active agent solution at room temperature for about 30 seconds to three minutes, and then washed with pure water. Then, the substrate 10 is sufficiently dried in a room temperature atmosphere. When the surface potential of the substrate 10 is a negative potential, the use of the anionic system surface-active agent can improve potential nonuniformity caused by dirt or the like on the surface of the substrate 10, and form a stable negative potential surface.

A catalyst (plating catalyst) 30 is provided in the first and second areas 12 and 14 of the substrate 10, as shown in FIG. 2(A). In this case, the substrate 10 may be dipped in a catalyst liquid 32. When the surface-active agent 26 is provided in the first and second areas 12 and 14, the catalyst 30 is provided on the surface-active agent 26. Alternatively, the catalyst 30 may be provided on the surface of the substrate 10 without the surface-active agent 26. The catalyst 30 causes the precipitation of a metal layer (plating layer) in an electroless plating liquid, and may be, for example, palladium. A resin for bonding may not be included in the catalyst 30.

For example, when the catalyst adhesion side is at a positive potential, the substrate 10 is dipped in a catalyst liquid including tin-palladium. More specifically, the substrate 10 is dipped in a tin-palladium colloid catalyst liquid of approximately PHi for 30 seconds-three minutes at room temperature, and then sufficiently washed with clear water. Tin-palladium colloidal particle has a negative charge, and adheres to the cationic system surface-active agent on the substrate 10. Then, the substrate 10 is dipped in a solution including a fluoroborate acid at room temperature for 30 seconds-three minutes for activation of the catalyst, and then washed with clear water. As a result, the tin colloidal particle is removed, and palladium alone can be precipitated.

Alternatively, when the catalyst adhesion side is at a negative potential, for example, the substrate 10 may be dipped successively in a solution including tin chloride and a catalyst liquid including palladium chloride. More specifically, the substrate 10 may be dipped in a tin chloride (II) solution for 1-5 minutes, and then washed with pure water, further the substrate 10 may be dipped in a palladium chloride (II) solution as a catalyst liquid for 1-5 minutes, and then is washed with pure water.

Besides the abovementioned method, the catalyst 30 may be provided in the first and second areas 12 and 14 of the substrate 10 by a dry film forming method (for example, by a sputter method or a vapor deposition method).

As shown in FIG. 2(B), portions of the catalyst 30 provided in the second area 14 are removed by washing the substrate 10 (for example, by wet washing). By washing the substrate 10, portions in the substrate 10 where the interatomic bond is broken down by the vacuum ultraviolet radiation 18 may be removed. When the surface-active agent 26 is provided, both of the surface-active agent 26 and the catalyst 30 are removed. As the washing method, the substrate 10 may be dipped in a washing solution 34, or a shower thereof may be jetted to the substrate 10. An alkaline solution (a strong alkaline solution or a weak alkaline solution) or pure water may be used as the washing solution 34. Shower washing with pure water or high-pressure jet washing with pure water may be applied as the shower method. Supersonic vibration may be added at the time of washing. In the example shown in FIG. 2(B), by conducting the washing, the catalyst 30 (and the surface-active agent 26) remains in the first area 12. The surface of the substrate 10 (for example, a newly generated surface in which an upper part thereof is removed) is exposed in the second area 14. In this manner, patterning is conducted to leave the catalyst 30 along the first area 12.

A metal layer 36 is deposited to a portion of the catalyst 30 left in the first area 12, as shown in FIG. 2(C). Because the catalyst 30 has been removed in the second area 14, the metal layer 36 is not precipitated to the second area 14. In this manner, the metal layer 36 can be formed in a pattern configuration along the first area 12. The metal layer 36 may be formed with one layer, or may be formed with multiple layers. The material of the metal layer 36 is not limited, and may be, for example, any one of Ni, Au, Ni+Au, Cu, Ni+Cu and Ni+Au+Cu. A catalyst may be selected according to the material of the metal layer 36 to be deposited.

In the example shown in FIG. 2(C), the substrate 10 is dipped in a plating solution 38 mainly containing nickel sulfate hexahydrate (at a temperature of 80° C.) for about one minute-three minutes, to form a nickel layer having a thickness of about 0.1-0.2 μm. Alternatively, the substrate 10 may be dipped in a plating solution mainly containing nickel chloride hexahydrate (at a temperature of 60° C.) for about three minutes-ten minutes, to form a nickel layer having a thickness of about 0.1-0.2 μm. According to the present embodiment, because the catalyst 30 is provided along the first area 12, the metal layer 36 can be selectively formed along the first area 12 of the substrate 10 even without forming a mask with a resist layer or the like.

In this manner, a wiring composed of the metal layer 36 can be formed along the first area 12. A wiring substrate in accordance with the present embodiment includes the substrate 10 and the metal layer (wiring) 36. A plurality of wirings may be formed on the substrate 10, to thereby form one wiring pattern.

In accordance with the present embodiment, the catalyst 30 is patterned by irradiating the vacuum ultraviolet radiation 18. As a result, the metal layer 36 can be deposited only to a required portion along a predetermined pattern configuration. Therefore, for example, there is no need to form a mask with a resist layer or the like, and a waste of material can be reduced, and wirings can be formed at a low cost with high accuracy, with a simple and short-time manufacturing process.

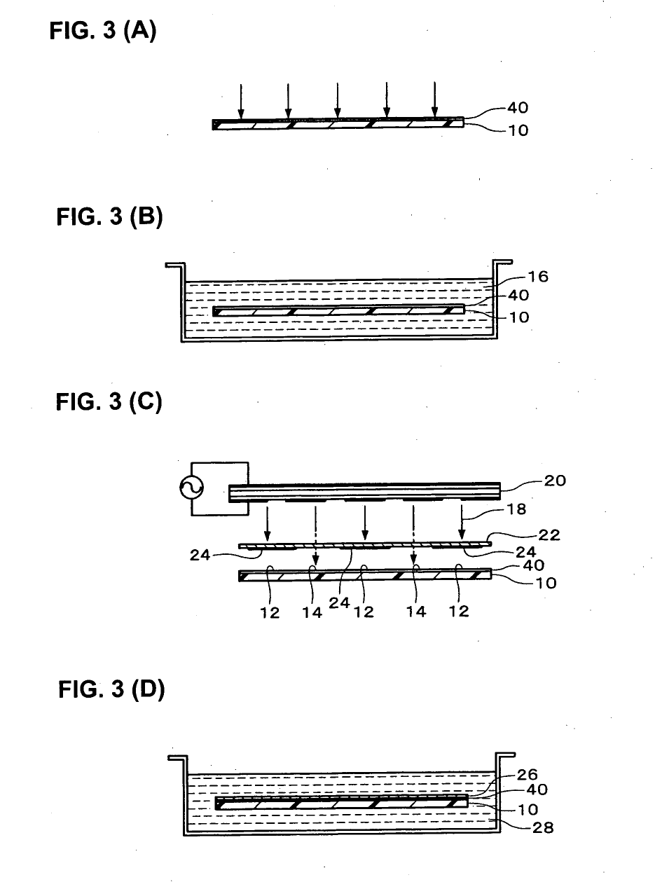

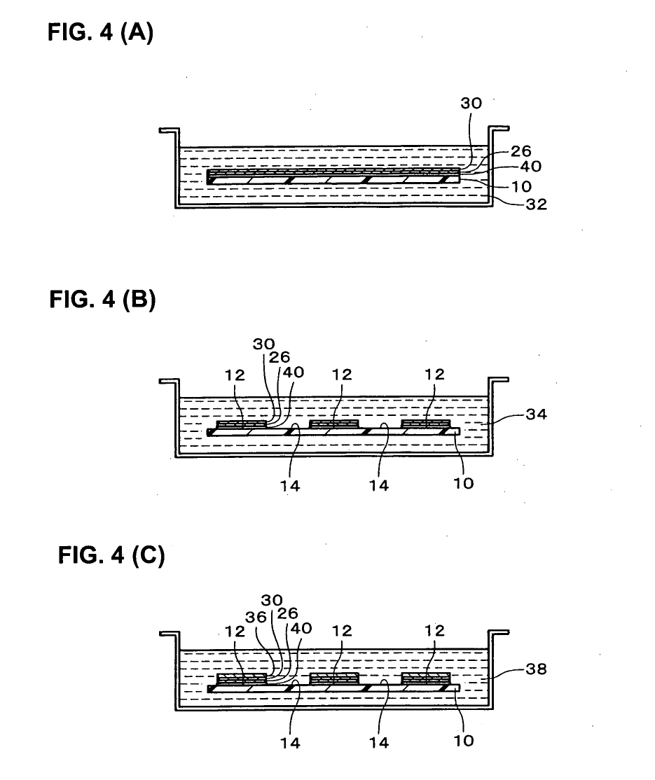

FIG. 3(A)-FIG. 4(C) are views illustrating a method of manufacturing a wiring substrate in accordance with a first modified example of the first embodiment of the present invention. In this modified example, a reforming layer (fluorinated layer) 40 including a C—F bond is formed to a substrate 10, as shown in FIG. 3(A). In other words, a fluorination treatment is applied to the substrate 10. The reforming layer 40 is formed in a surface layer portion on the side of first and second areas 12 and 14 of the substrate 10. The reforming layer 40 may be formed on the entire area of one of the surfaces of the substrate 10. For example, a plasma surface treatment may be applied to the substrate 10 by using a CF₄ gas. Though the thickness of the reforming layer 40 is not limited, it may be, for example, about 10 nm or less. Effects similar to the cleaning and surface roughening treatment of the substrate 10 described above can be achieved by forming the reforming layer 40. Moreover, the moisture resistance of the substrate 10 improves because the reforming layer 40 has a water-repelling function. Therefore, for example, even when it is kept for about one month in an indoor environment up to the catalyst formation process after irradiation of the vacuum ultraviolet radiation 18, the reproducibility of the pattern can be maintained.

Then, dirt on the surface of the substrate 10 may be further washed if necessary (see FIG. 3(B)), a vacuum ultraviolet radiation 18 is irradiated to the substrate 10 (see FIG. 3(C)), a surface-active agent 26 is provided on a reforming layer 40 (see FIG. 3(D)), and a catalyst 30 is provided on the surface-active agent 26 (see FIG. 4(A)). Then, portions of the substrate 10 where the interatomic bond is broken down are removed by washing the substrate 10 (see FIG. 4(B)). In this manner, a wiring can be formed along a predetermined pattern configuration (the first area 12) by precipitating a metal layer 36 to portions where the catalyst 30 remains, as shown in FIG. 4(C). The contents described above can be applied to details of the above.

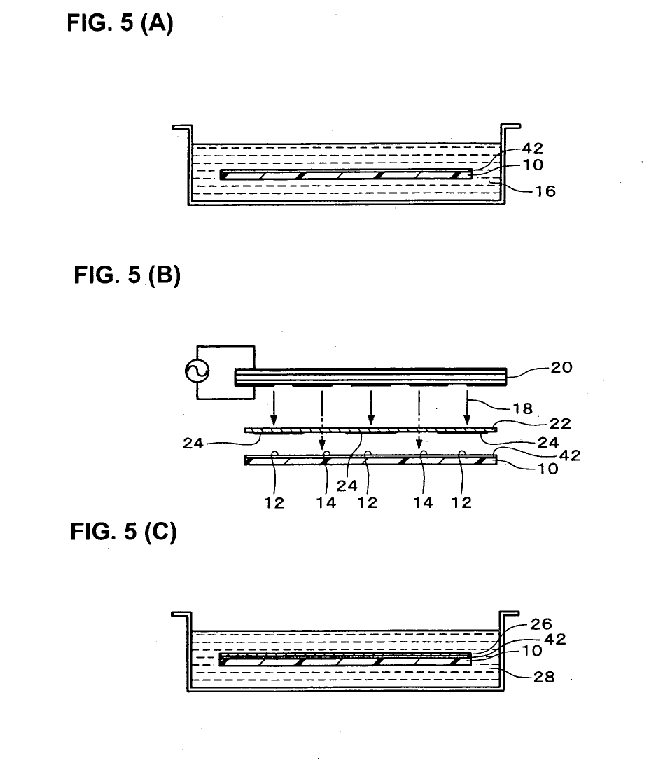

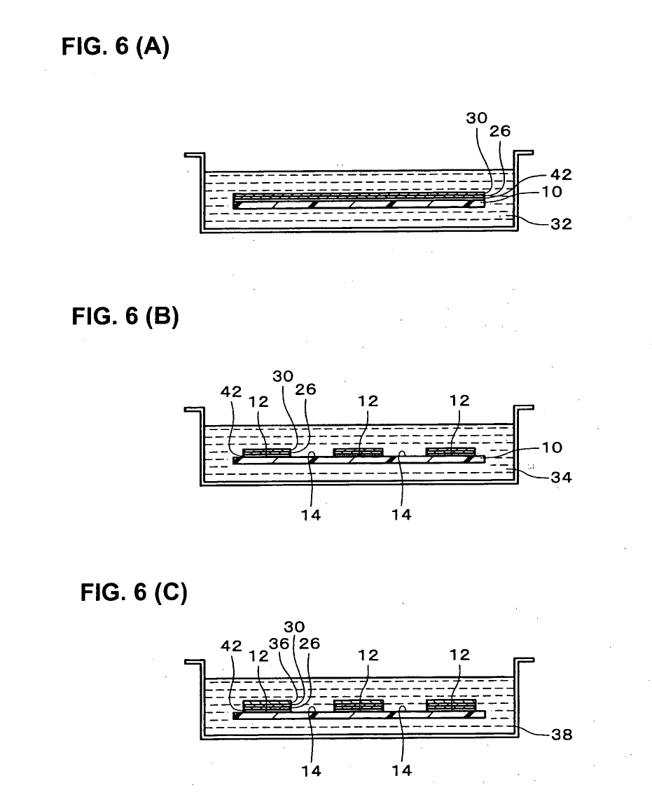

FIG. 5(A)-FIG. 6(C) are views illustrating a method of manufacturing a wiring substrate in accordance with a second modified example of the first embodiment of the present invention. In this modified example, a substrate 10 is washed with alkali, to thereby form a hydrolyzed layer 42 to the substrate 10. The hydrolyzed layer 42 is formed in a surface layer portion on the side of first and second areas 12 and 14 of the substrate 10. Alkali washing may be conducted by dipping the substrate 10 in a washing solution 16 such as an alkaline solution (for example, an inorganic alkaline solution) or the like, as shown in FIG. 5(A). More specifically, the substrate 10 may be dipped in sodium hydroxide in a concentration of 10 wt %-20 wt % at room temperature for about 10 minutes-60 minutes, and washed with clear water. The thickness of the hydrolyzed layer 42 can be adjusted by various factors, such as, a liquid temperature and liquid concentration of the washing solution 16 that may be an alkaline solution, or the like, and the washing time. It is noted that cleaning and surface roughening treatment of the substrate 10 can be conducted at the same time by the above-described alkali washing. By this, the adhesion of a metal layer (wiring) can be improved.

Then, a vacuum ultraviolet radiation 18 is irradiated to the substrate 10 (see FIG. 5(B)), a surface-active agent 26 is provided on the hydrolyzed layer 42 (see FIG. 5(C)), and a catalyst 30 is provided on the surface-active agent 26 (see FIG. 6(A)). Then, portions of the substrate 10 where the interatomic bond is broken down are removed by washing the substrate 10 (see FIG. 6(B)). In this manner, a wiring can be formed along a predetermined pattern configuration (the first area 12) by precipitating a metal layer 36 to portions where the catalyst 30 remains, as shown in FIG. 6 (C). The contents described above can be applied to details of the above.

In the first and second modified examples, the vacuum ultraviolet radiation is injected into a portion (for example, 1 μm deep or less from the surface) deeper than the surface layer portion of the substrate (where the reforming layer 40 or the hydrolyzed layer 42 is formed). Stated otherwise, the thickness of the surface layer portion is formed thinner than the incident depth of the vacuum ultraviolet radiation. As a result, the interatomic bond at least between the surface layer portion of the substrate 10 and other parts is broken down. In other words, when the surface layer portion of the substrate 10 is formed from the reforming layer 40, the interatomic bond between the reforming layer 40 of the substrate 10 and other parts can be broken down. Alternatively, when the surface layer portion of the substrate 10 is formed from the hydrolyzed layer 42, the interatomic bond between the hydrolyzed layer 42 of the substrate 10 and other parts can be broken down. According to this, because the surface layer portion of the substrate 10 can be readily removed, the catalyst 30 can be securely left for a predetermined pattern configuration (a configuration along the first area 12), and a highly accurate wiring can be readily formed.

### Second Embodiment

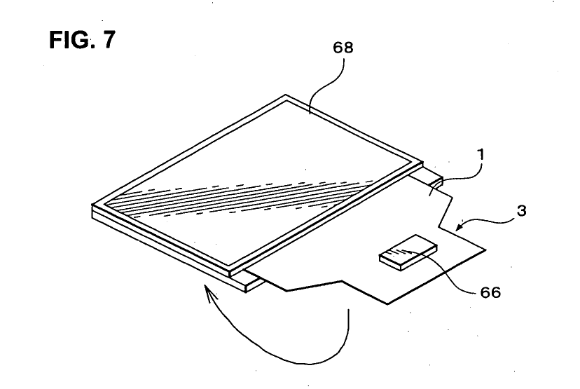

FIG. 7 is a view for describing a method for manufacturing an electronic device in accordance with a second embodiment of the present invention, and more particularly, shows an example of an electronic device having a wiring substrate.

A metal layer (omitted in FIG. 7) having a predetermined pattern configuration is formed in a wiring substrate 1. A semiconductor chip 66 having an integrated circuit may be mounted (for example, face-down mounted) on the wiring substrate 1. The semiconductor chip 66 (integrated circuit) is electrically connected to the metal layer. In this manner, the semiconductor device 3 including the semiconductor chip 66 and the wiring substrate 1 may be manufactured. Then, the wiring substrate 1 (or, the semiconductor device 3) is electrically connected to a circuit board 68. Thus, the electronic device can be manufactured. It is noted that the wiring substrate 1 may be bent, as indicated by an arrow in FIG. 7.

When the circuit board 68 is an electrooptic panel, the electronic device is an electrooptic device. The electrooptic device may be a liquid crystal device, a plasma display device, an electroluminescence display device, or the like. In accordance with the present embodiment, a waste of material can be reduced, and wirings can be formed at a low cost with high accuracy, with a simple and short-time manufacturing process.

The present invention is not limited to the embodiments described above, and many modifications can be made. For example, the present invention may include compositions that are substantially the same as the compositions described in the embodiments (for example, a composition with the same function, method and result, or a composition with the same objects and result). Also, the present invention includes compositions in which portions not essential in the compositions described in the embodiments are replaced with others. Also, the present invention includes compositions that achieve the same functions and effects or achieve the same objects of those of the compositions described in the embodiments. Furthermore, the present invention includes compositions that include publicly known technology added to the compositions described in the embodiments.

1. A method for manufacturing a wiring substrate comprising the steps of:
(a) irradiating a vacuum ultraviolet radiation to a second area of a substrate having a first area and the second area to thereby break down an interatomic bond in the second area of the substrate;
(b) providing a catalyst in the first and second areas of the substrate;
(c) washing the substrate to thereby remove a portion of the catalyst provided in the second area; and
(d) depositing a metal layer on a portion of the catalyst remaining in the first area to thereby form a wiring composed of the metal layer along the first area.

2. A method for manufacturing a wiring substrate according to claim 1, wherein, before the step (a), a surface layer portion composed of a reforming layer including a C—F bond in the first and second areas of the substrate is formed.

3. A method for manufacturing a wiring substrate according to claim 1, wherein, before the step (a), a surface layer portion composed of a hydrolyzed layer in the first and second areas of the substrate is formed by conducting an alkaline washing.

4. A method for manufacturing a wiring substrate according to claim 2, wherein,
in the step (a), the vacuum ultraviolet radiation is injected deeper than the thickness of the surface layer portion, and
in the step (c), the substrate is washed to thereby remove a portion of the surface layer portion in the second area.

5. A method for manufacturing a wiring substrate according to claim 1, further comprising, before the step (b), the step of providing a surface-active agent in the first and second areas of the substrate, wherein, in the step (b), the catalyst is provided on the surface-active agent.

6. A method for manufacturing a wiring substrate according to claim 5, wherein the surface-active agent is a cationic system surface-active agent.

7. A method for manufacturing a wiring substrate according to claim 5, wherein the surface-active agent is an anionic system surface-active agent.

8. A method for manufacturing a wiring substrate according to claim 1, wherein, in the step (b), the substrate is dipped in a solution including tin chloride, and then dipped in a catalyst liquid including palladium chloride, to thereby deposit palladium as the catalyst.

9. A method for manufacturing a wiring substrate according to claim 1, wherein, in the step (b), the substrate is dipped in a catalyst liquid including tin-palladium to remove tin from the substrate, to thereby deposit palladium as the catalyst.

10. A method for manufacturing a wiring substrate according to claim 1, wherein the substrate has at least one of a C—C, C═C, C—F, C—H, C—Cl, C—N, C—O, N—H and O—H bond.

11. A method for manufacturing a wiring substrate according to claim 1, wherein the substrate has at least a C═C bond, and the vacuum ultraviolet radiation has at least a property that can break down the C═C bond.

12. A method for manufacturing a wiring substrate according to claim 1, wherein a light source of the vacuum ultraviolet radiation is an excimer lamp having Xe gas enclosed therein.

13. A method for manufacturing an electronic device, comprising:
the method for manufacturing a wiring substrate according to claim 1, and further comprising the steps of mounting a semiconductor chip having an integrated circuit on the wiring substrate, and electrically connecting the wiring substrate to a circuit substrate.
